(19) United States
(12) Patent Application Publication
(10) Pub. No.: US 2024/0171143 A1
(43) Pub. Date: May 23, 2024

(54) DIFFERENTIAL AMPLIFIER CIRCUIT AND ELECTRONIC DEVICE

(71) Applicant: DECO lntegration Technology Co.,Limited, Shenzhen (CN)

(72) Inventors: Cheng LI, Shenzhen (CN); Tso Wei LI, Shenzhen (CN)

(73) Assignee: DECO lntegration Technology Co.,Limited, Shenzhen (CN)

(21) Appl. No.: 18/080,727

(22) Filed: Dec. 13, 2022

(30) Foreign Application Priority Data
Nov. 23, 2022 (CN) 202211476297.X

(51) Int. Cl. H03F 3/45; H03F 1/32

(52) U.S. Cl. CPC H03F 3/45475; H03F 1/3211; H03F 2200/372; H03F 2200/541

(57) ABSTRACT

Disclosed are a differential amplifier circuit and an electronic device. The differential amplifier circuit includes a plurality of differential amplifiers and a plurality of transformers. The plurality of differential amplifiers are connected in series. Each of the differential amplifiers is correspondingly connected to one of the transformers, and one of the transformers is connected between different differential amplifiers. At least one of the differential amplifiers is invertedly connected to the corresponding transformer. By invertedly connecting the transformer to at least one differential amplifier, a ground bounce signal generated by the invertedly connected differential amplifier is inverted, and has a phase opposite to phases of ground bounce signals generated by other normally connected differential amplifiers, such that at least a part of the ground bounce signals can be canceled, thereby improving a ground bounce effect, reducing phase distortion, and enhancing the stability of the series differential amplifiers.

### CROSS-REFERENCE TO RELATED APPLICATIONS

The application claims priority to Chinese patent application No. 202211476297.X, filed on Nov. 23. 2022, the entire contents of which are incorporated herein by reference.

### TECHNICAL FIELD

The present disclosure relates to the field of differential amplifiers, in particular to a differential amplifier circuit and an electronic device.

### BACKGROUND

The current mainstream microwave amplifier is an amplifier with a differential structure. As shown in FIG. 1, it is a series differential amplifier formed by connecting amplifier units (AMP_1, AMP_2, . . . , AMP_N) in series. A transformer (TF_1, TF_2, . . . , TF N) is connected to the back end of each amplifier unit, and completes impedance matching between stages, such that simplicity and small area are achieved.

FIG. 2 is a detailed differential amplifier circuit. In the amplifier units, transistors M1, M2, M3, and M4 constitute the amplifier in which many bypass capacitors are required to provide ideal low impedance. The bypass capacitors are usually connected to grounds which can be referred to as ideal grounds for providing ideal signal suppression for the amplifier.

However, in an actual amplifier, especially in a high-frequency millimeter wave band, ideal nodes will produce a parasitic effect, which will make a non-ideal effect more obvious.

FIG. 3 shows a schematic diagram of the parasitic effect generated by the series differential amplifier, in which Lgnd is a non-ideal equivalent inductor. Signals will be transmitted on non-ideal inductors, that is to say, ground bounce signals will be generated. These ground bounce signals will produce in phase combination in a circuit loop, thereby affecting phases and causing phase distortion and stability problem of the series differential amplifier.

### SUMMARY

To solve the technical problems, the present disclosure provides a differential amplifier circuit and an electronic device, which can improve a ground bounce effect.

To solve the above technical problems, the present disclosure adopts a technical solution as follows:

A differential amplifier circuit, including a plurality of differential amplifiers and a plurality of transformers, where

the plurality of differential amplifiers are connected in series;

each of the differential amplifiers is correspondingly connected to one of the transformers, and one of the transformers is connected between different differential amplifiers; and

at least one of the differential amplifiers is invertedly connected to the corresponding transformer.

To solve the above technical problems, the present disclosure adopts another technical solution as follows:

An electronic device, including the above differential amplifier circuit.

The present disclosure has the following beneficial effects: in the series differential amplifier circuit, each differential amplifier is correspondingly connected to one transformer, and one transformer is connected between different differential amplifiers; and at least one of the differential amplifiers is invertedly connected to the corresponding transformer. By invertedly connecting the transformer to at least one differential amplifier, a ground bounce signal generated by the invertedly connected differential amplifier is inverted, and has a phase opposite to phases of ground bounce signals generated by other normally connected differential amplifiers, such that at least a part of the ground bounce signals can be canceled, thereby improving the ground bounce effect, reducing phase distortion, and enhancing the stability of the series differential amplifiers.

### BRIEF DESCRIPTION OF DRAWINGS

FIG. 1 is a schematic structural diagram of a series differential amplifier in the prior art:

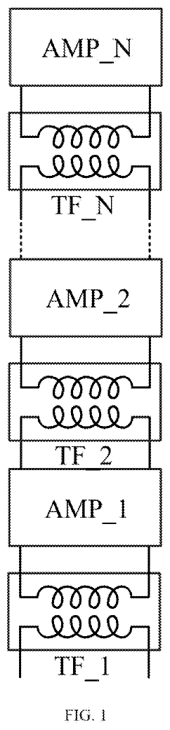

FIG. 2 is a schematic structural diagram of a series differential amplifier connected to bypass capacitors in the prior art;

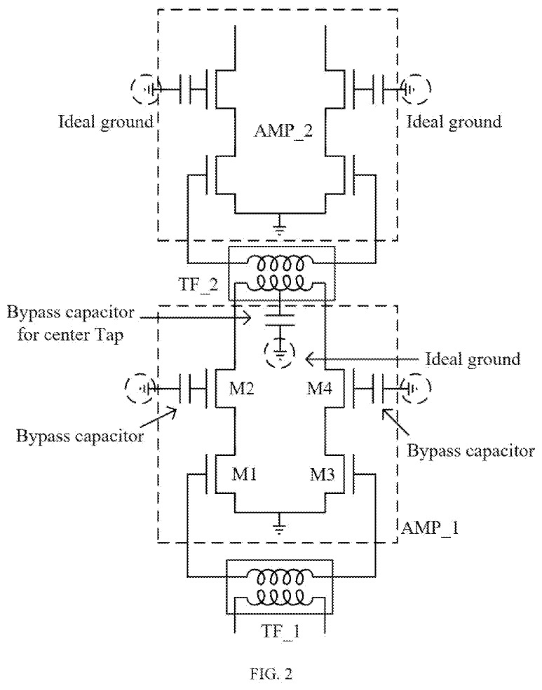

FIG. 3 is a schematic diagram of a parasitic effect generated by the series differential amplifier in the prior art;

FIG. 4 is a schematic structural diagram of a differential amplifier circuit according to an embodiment of the present disclosure; and

FIG. 5 is a diagram of simulative comparison between the differential amplifier circuit according to the embodiment of the present disclosure and an existing differential amplifier circuit.

### DETAILED DESCRIPTION OF THE EMBODIMENTS

The technical content, achieved objective and effect of the present disclosure are described in detail below with reference to the embodiments and the accompanying drawings.

The above differential amplifier circuit and electronic device according to the present disclosure can be applicable to the series differential amplifiers to improve the ground bounce effect, which is described through the specific embodiments below.

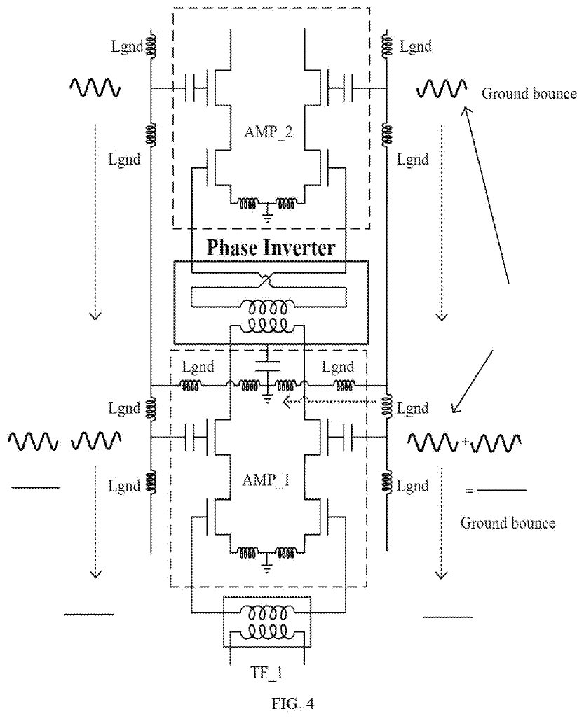

In one optional embodiment, referring to FIG. 4, a differential amplifier circuit includes a plurality of differential amplifiers and a plurality of transformers, where

the plurality of differential amplifiers are connected in series;

each of the differential amplifiers is correspondingly connected to one of the transformers, and one of the transformers is connected between different differential amplifiers; and

at least one of the differential amplifiers is invertedly connected to the corresponding transformer.

Herein, in the inverted connection between at least one of the differential amplifiers and the corresponding transformer,

the connection between at least one of the differential amplifiers and the corresponding transformer is inverted-phase connection, and the connection between other differential amplifiers and the corresponding transformers is same-phase connection.

Herein, the differential amplifier can adapt to different wave bands. In this embodiment, it is a microwave differential amplifier, that is to say, in this embodiment, the differential amplifier works in a microwave band, such as a high-frequency millimeter wave band.

Specifically, in the inverted connection between the differential amplifier and the corresponding transformer,

an output terminal of the differential amplifier is invertedly connected to an input terminal of the corresponding transformer.

In this embodiment, as shown in FIG. 4, the differential amplifier circuit includes two differential amplifiers AMP_1 and AMP_2 connected in series. Each differential amplifier is connected to one corresponding transformer, that is to say, one transformer is connected between the two differential amplifiers AMP_1 and AMP_2. Two output terminals of the differential transformer AMP_2 are invertedly connected to two input terminals of the corresponding transformer, namely, cross connection is presented, that is to say, the connection therebetween is inverted-phase connection, while the connection between two output terminals of the differential transformer AMP_1 and two input terminals of the corresponding transformer is same-phase connection. Specifically, for example, when the two output terminals of the differential transformer AMP_2 are Vout2+ and Vout2−, respectively, the two input terminals of the transformer corresponding to the differential transformer AMP_2 are Tin2+ and Tin2−, respectively, the two output terminals of the differential transformer AMP_1 are Vout1+ and Vout1−, respectively, and the two input terminals of the transformer corresponding to the differential amplifier AMP_1 are Tin1+ and Tin1−, respectively, Vout2+ is connected to Tin2−, Vout2− is connected to Tin2+, Vout1+ is connected to Tin1+, and Vout1− is connected to Tin1−.

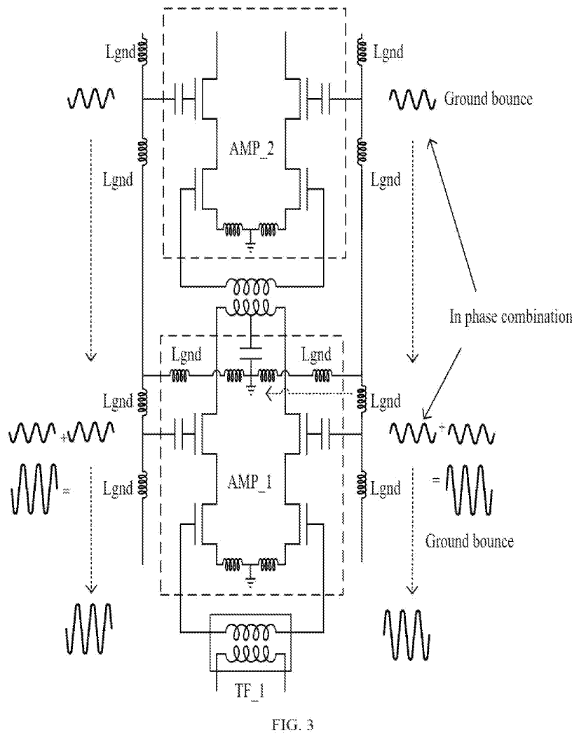

FIG. 3 is a schematic waveform diagram of a ground bounce signal generated by a series differential amplifier, in the prior art, corresponding to the differential amplifier circuit described in FIG. 4 in this embodiment. In FIG. 3, the connection between each differential amplifier and the corresponding transformer is conventional connection, namely, the same-phase connection.

By comparing the waveform diagrams of the ground bounce signal shown in FIG. 3 and FIG. 4, it may be seen that in FIG. 3, the ground bounce signal generated by each differential amplifier has the same phase, so in phase combination will occur, and the larger the ground bounce signal after combination is, the greater the impact on the stability of the series differential amplifier is; and in FIG. 4, the connection between one differential amplifier AMP_2 and the corresponding transformer is the inverted-phase connection, so the ground bounce signal generated by the differential amplifier AMP_2 is inverted, while the ground bounce signal generated by the other differential amplifier AMP_1 is forward, and the ground bounce signals generated by the two differential amplifiers just cancel each other, thus greatly reducing the size of the ground bounce signal and effectively improving the stability and phase distortion of the series differential amplifier.

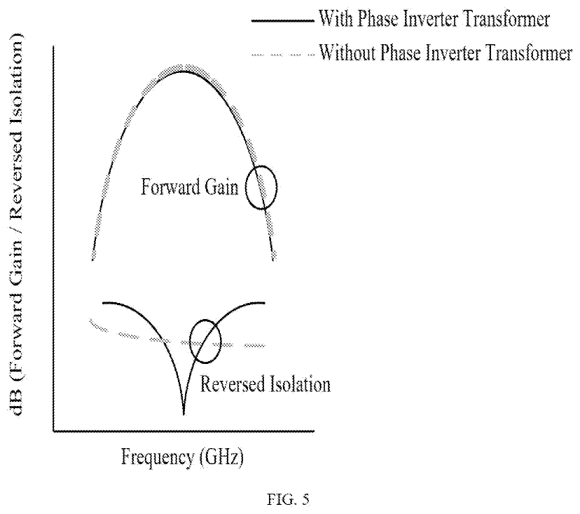

FIG. 5 shows a diagram of simulative comparison between the differential amplifier circuit in this embodiment and an existing differential amplifier circuit, in which an abscissa represents a frequency, an ordinate represents forward gain or reversed isolation, the smaller the isolation is, the better the result is, a dashed line represents the existing differential amplifier circuit, and a solid line represents the invertedly connected differential amplifier circuit in this embodiment. It may be seen from the comparison diagram that in a case where the forward gain is appropriate, the reversed isolation of the differential amplifier circuit in this embodiment is well improved compared to the existing differential amplifier circuit.

In one optional embodiment, the differential amplifier of each stage includes two parallel branches connected in parallel; and each parallel branch includes one transistor, that is to say, the differential amplifier of each stage includes two transistors connected in parallel, which may be connected in the following manner: gates of the two transistors serve as input terminals, drains thereof serve as output terminals, and sources thereof are grounded.

In another optional embodiment, the differential amplifier of each stage includes two parallel branches connected in parallel; each parallel branch includes two transistors connected in series, that is to say, the differential amplifier of each stage includes four transistors, and each parallel branch has two transistors connected in series; and for example, the two transistors of the first parallel branch are M1 and M2, the two transistors of the second parallel branch are M3 and M4, M1 corresponds to M3, M2 corresponds to M4, and the transistors may be connected in the following manner: drains of M1 and M3 serve as output terminals, gates of M1 and M3 are connected to bypass capacitors and then are grounded, a source of M1 is connected to a drain of M2, a source of M3 is connected to a drain of M4, gates of M2 and M4 serve as input terminals, and sources of M2 and M4 are connected to inductors and then are grounded.

If the connection between the differential amplifier of each stage and the corresponding transformer is the same-phase connection like the existing conventional connection, then the generated ground bounce signal will be the combination of the ground bounce signal generated by the differential amplifier of each stage. If the connection between the differential amplifier of at least one stage and the corresponding transformer is the inverted-phase connection, then the ground bounce signal generated by the differential amplifier of this stage will be inverted, and can at least partially cancel the ground bounce signals generated by other conventionally connected differential amplifiers. Therefore, the ground bounce signal generated by the differential amplifier circuit using the above connection manner will be smaller than the ground bounce signal generated by the existing differential amplifier circuit.

Herein, the number and positions of differential amplifiers that are connected invertedly may be set flexibly.

In one optional embodiment, the connection between half of the differential amplifiers connected in series and the corresponding transformers may be set to be the inverted-phase connection, and the connection between other differential amplifiers and the corresponding transformers may be set to be the same-phase connection. By setting the number of differential amplifiers subjected to the inverted-phase connection to be close to the number of differential amplifiers subjected to the in-phase connection, the more the ground bounce signals that can cancel each other is, the smaller the finally obtained ground bounce signal is.

A first implementation mode may be that the connection between the differential amplifiers of even stages in the differential amplifiers connected in series and the corresponding transformers is the inverted-phase connection, and the connection between the differential amplifiers of odd stages and the corresponding transformers is the same-phase connection; or

the connection between the differential amplifiers of even stages in the differential amplifiers connected in series and the corresponding transformers is the same-phase connection, and the connection between the differential amplifiers of odd stages and the corresponding transformers is the inverted-phase connection.

For example, if the differential amplifiers of four stages are connected in series, then the differential amplifier of a first stage and the differential amplifier of a third stage may be set to be in inverted-phase connection with the corresponding transformers, respectively, and the differential amplifier of a second stage and the differential amplifier of a fourth stage may be set to be in in-phase connection with the corresponding transformers, respectively; or the differential amplifier of the first stage and the differential amplifier of the third stage may be set to be in in-phase connection with the corresponding transformers, respectively, and the differential amplifier of the second stage and the differential amplifier of the fourth stage may be set to be in inverted-phase connection with the corresponding transformers, respectively.

For example, if the differential amplifiers of five stages are connected in series, then the differential amplifier of a first stage, the differential amplifier of a third stage, and the differential amplifier of a fifth stage may be set to be in inverted-phase connection with the corresponding transformers, respectively, and the differential amplifier of a second stage and the differential amplifier of a fourth stage may be set to be in in-phase connection with the corresponding transformers, respectively; or the differential amplifier of the first stage, the differential amplifier of the third stage, and the differential amplifier of the fifth stage may be set to be in in-phase connection with the corresponding transformers, respectively, and the differential amplifier of the second stage and the differential amplifier of the fourth stage may be set to be in inverted-phase connection with the corresponding transformers, respectively.

In the above implementation mode, the connection of the differential amplifiers of all stages is implemented by alternating the in-phase connection and the inverted-phase connection, which can mutually cancel the ground bounce signals appearing in the circuit in time.

A second implementation mode may be that the connection between the differential amplifiers of first └N/2┘ stages in the differential amplifiers connected in series and the corresponding transformers is the inverted-phase connection, and the connection between other differential amplifiers and the corresponding transformers is the same-phase connection; or

the connection between the differential amplifiers of first └N/2┘ stages in the differential amplifiers connected in series and the corresponding transformers is the same-phase connection, and the connection between other differential amplifiers and the corresponding transformers is the inverted-phase connection, where N represents the number of stages of the plurality of differential amplifiers, and [symbol] represents downward rounding.

For example, if the differential amplifiers of four stages are connected in series, then the differential amplifier of a first stage and the differential amplifier of a second stage may be set to be in inverted-phase connection with the corresponding transformers, respectively. and the differential amplifier of a third stage and the differential amplifier of a fourth stage may be set to be in in-phase connection with the corresponding transformers, respectively; or the differential amplifier of the first stage and the differential amplifier of the second stage may be set to be in in-phase connection with the corresponding transformers, respectively. and the differential amplifier of the third stage and the differential amplifier of the fourth stage may be set to be in inverted-phase connection with the corresponding transformers, respectively.

For example, if the differential amplifiers of five stages are connected in series, then the differential amplifier of a first stage and the differential amplifier of a second stage may be set to be in inverted-phase connection with the corresponding transformers, respectively, and the differential amplifier of a third stage, the differential amplifier of a fourth stage, and the differential amplifier of a fifth stage may be set to be in in-phase connection with the corresponding transformers, respectively; or the differential amplifier of the first stage and the differential amplifier of the second stage may be set to be in in-phase connection with the corresponding transformers, respectively, and the differential amplifier of the third stage, the differential amplifier of the fourth stage, and the differential amplifier of the fifth stage may be set to be in inverted-phase connection with the corresponding transformers, respectively.

In the above implementation mode, in a unified way, the first half of the differential amplifiers connected in series are set to be connected in one manner, while the second half of the differential amplifiers connected in series are set to be connected in another manner, which can greatly facilitate the connection of the differential amplifiers of multiple stages and improve the assembly efficiency.

In another optional embodiment, the plurality of differential amplifiers connected in series may be divided into M groups, where the number of stages of M-1 groups of the differential amplifiers is └N/M┘, N represents the number of stages of the plurality of differential amplifiers connected in series, [symbol] represents downward rounding, and the number of stages of a remaining group of the differential amplifiers is N−(M−1)*└N/M┘.

The connection between the differential amplifiers in the even group and the corresponding transformers is set to be the same-phase connection, and the connection between the differential amplifiers in the odd group and the corresponding transformers is set to be the inverted-phase connection; or

the connection between the differential amplifiers in the even group and the corresponding transformers is set to be the inverted-phase connection, and the connection between the differential amplifiers in the odd group and the corresponding transformers is set to be the same-phase connection.

For example, if the differential amplifiers of a total of eight stages are connected in series and the differential amplifiers of the eight stages connected in series are divided into four groups, then the number of stages of the differential amplifiers in each group is two, the differential amplifiers in first and third groups may be set to be in inverted-phase connection with the corresponding transformers, respectively, and the differential amplifiers in second and fourth groups may be set to be in same-phase connection with the corresponding transformers, respectively, or the differential amplifiers in the first and third groups may be set to be in same-phase connection with the corresponding transformers, respectively, and the differential amplifiers in the second and fourth groups may be set to be in inverted-phase connection with the corresponding transformers, respectively.

For example, if the differential amplifiers of a total of nine stages are connected in series and the differential amplifiers of the nine stages connected in series are divided into four groups, then the number of stages of the differential amplifiers in each of first three groups is two, the number of stages of the differential amplifiers in a final group is three, the differential amplifiers in first and third groups may be set to be in inverted-phase connection with the corresponding transformers, respectively, and the differential amplifiers in second and fourth groups may be set to be in same-phase connection with the corresponding transformers. respectively, or the differential amplifiers in the first and third groups may be set to be in same-phase connection with the corresponding transformers, respectively, and the differential amplifiers in the second and fourth groups may be set to be in inverted-phase connection with the corresponding transformers, respectively.

In another optional embodiment, an electronic device includes the differential amplifier circuit described in any one of the above embodiments, and the differential amplifier circuit can be applied to various scenarios where the differential amplifiers need to be used.

In conclusion, according to the differential amplifier circuit and the electronic device provided by the present disclosure, in the series differential amplifier circuit, each differential amplifier is correspondingly connected to one transformer, and one transformer is connected between different differential amplifiers; and at least one of the differential amplifiers is invertedly connected to the corresponding transformer. By invertedly connecting the transformer to at least one differential amplifier, the ground bounce signal generated by the invertedly connected differential amplifier is inverted, and has a phase opposite to phases of the ground bounce signals generated by other normally connected differential amplifiers, such that at least a part of the ground bounce signals can be canceled, thereby improving the ground bounce effect, reducing the phase distortion, and enhancing the stability of the series differential amplifiers. Herein, the positions and number of differential amplifiers that are connected invertedly may be flexibly configured, such that the differential amplifiers may be set in half, at intervals, or in groups, thereby meeting the needs of various application scenarios. Therefore, high flexibility and strong adaptability are achieved.

The above descriptions are only the embodiments of the present disclosure, rather than limiting the scope of patent of the present disclosure. Any equivalent transformations made by using the content of the specification and the accompanying drawings of the present disclosure, directly or indirectly applied in related technical fields, are similarly included in the scope of patent protection of the present disclosure.

What is claimed is:

1. A differential amplifier circuit, comprising a plurality of differential amplifiers and a plurality of transformers, wherein
the plurality of differential amplifiers are connected in series;
each of the differential amplifiers is correspondingly connected to one of the transformers. and one of the transformers is connected between different differential amplifiers; and
at least one of the differential amplifiers is invertedly connected to the corresponding transformer.

2. The differential amplifier circuit according to claim 1, wherein in the inverted connection between at least one of the differential amplifiers and the corresponding transformer,
the connection between at least one of the differential amplifiers and the corresponding transformer is inverted-phase connection, and the connection between other differential amplifiers and the corresponding transformers is same-phase connection.

3. The differential amplifier circuit according to claim 1, wherein in the inverted connection between at least one of the differential amplifiers and the corresponding transformer,
the connection between half of the differential amplifiers connected in series and the corresponding transformers is inverted-phase connection, and the connection between other differential amplifiers and the corresponding transformers is same-phase connection.

4. The differential amplifier circuit according to claim 3, wherein the connection between the differential amplifiers of even stages in the differential amplifiers connected in series and the corresponding transformers is the inverted-phase connection, and the connection between the differential amplifiers of odd stages and the corresponding transformers is the same-phase connection; or
the connection between the differential amplifiers of even stages in the differential amplifiers connected in series and the corresponding transformers is the same-phase connection, and the connection between the differential amplifiers of odd stages and the corresponding transformers is the inverted-phase connection.

5. The differential amplifier circuit according to claim 3, wherein the connection between the differential amplifiers of first └N/2┘ stages in the differential amplifiers connected in series and the corresponding transformers is the inverted-phase connection, and the connection between other differential amplifiers and the corresponding transformers is the same-phase connection; or
the connection between the differential amplifiers of first └N/2┘ stages in the differential amplifiers connected in series and the corresponding transformers is the same-phase connection, and the connection between other differential amplifiers and the corresponding transformers is the inverted-phase connection, wherein N represents the number of stages of the plurality of differential amplifiers connected in series, and [symbol] represents downward rounding.

6. The differential amplifier circuit according to claim 1, wherein in the inverted connection between at least one of the differential amplifiers and the corresponding transformer,
the plurality of differential amplifiers connected in series are divided into M groups, wherein the number of stages of M-1 groups of the differential amplifiers is └N/M┘, N represents the number of stages of the plurality of differential amplifiers connected in series, [symbol] represents downward rounding, and the number of stages of a remaining group of the differential amplifiers is M−(M−1)*└N/M┘,
the connection between the differential amplifiers in the even group and the corresponding transformers is set to be same-phase connection, and the connection between the differential amplifiers in the odd group and the corresponding transformers is set to be inverted-phase connection; or
the connection between the differential amplifiers in the even group and the corresponding transformers is set to be inverted-phase connection, and the connection between the differential amplifiers in the odd group and the corresponding transformers is set to be same-phase connection.

7. The differential amplifier circuit according to claim 1, wherein in the inverted connection between each of the differential amplifier and the corresponding transformer,
an output terminal of each of the differential amplifiers is invertedly connected to an input terminal of the corresponding transformer.

8. The differential amplifier circuit according to claim 1, wherein each of the differential amplifiers comprises two parallel branches connected in parallel, and each parallel branch comprises one transistor or two transistors connected in series.

9. The differential amplifier circuit according to claim 1, wherein the differential amplifiers are microwave differential amplifiers.

10. An electronic device, comprising the differential amplifier circuit according to claim 1.
